(19) United States
(12) Patent Application Publication
(10) Pub. No.: US 2012/0112218 A1
(43) Pub. Date: May 10, 2012

(54) Light Emitting Diode with Polarized Light Emission

(75) Inventors: Jinghua Teng, Singapore (SG); Soo-Jin Chua, Singapore (SG); Liang Zhang, Singapore (SG); Liyuan Deng, Singapore (SG)

(73) Assignee: AGENCY FOR SCIENCE, TECHNOLOGY AND RESEARCH, Singapore (SG)

(21) Appl. No.: 12/939,322

(22) Filed: Nov. 4, 2010

(51) Int. Cl. H01L 33/38

(52) U.S. Cl. 257/98; 438/27; 257/E33.065; 257/E33.057

(57) ABSTRACT

An apparatus for emitting polarized light and a method for fabricating such apparatus are provided. The apparatus includes a surface emission light emitting diode (LED), a first electrode, and a sub-wavelength metal grating (SWMG). The surface emission LED includes a first contact surface and a second contact surface. The first electrode is coupled to the first contact surface. The SWMG is formed on a surface of the surface emission LED.

### TECHNICAL FIELD

The present invention generally relates to light emitting diodes (LEDs), and more particularly relates to LEDs with polarized light emission.

### BACKGROUND OF THE DISCLOSURE

Light emitting diodes (LEDs) have become important light sources in many applications such as solid state lighting, back lighting, signaling and displays. The increase in importance of LEDs to these applications is due in part to the success of InGaN materials and LED device development. As in conventional light sources, the LEDs are non-coherent and non-polarized light sources, i.e. light does not possess a significant preference for a specific polarization state. However, for some applications, such as LCD backlighting, LCD projection, and liquid crystal (LC)-beam steering devices in which the light beam emitted by LED point sources is manipulated with LC cells, the non-polarized light from LEDs must be converted to polarized light through a polarizer in order for the next layer of LC to switch the light from LEDs on and off. The polarizer adds cost and complexity to such displays. Thus, such displays, particularly flat panel displays, can be manufactured thinner and at less cost if the LED can emit polarized light directly.

Several methods for emission of polarized light from LEDs have been proposed. For example, research has been done in growing GaN LEDs in non-polar or semi-polar substrates, using photonic crystal structures for LEDs, or using special reflector designs for packaged LEDs. Yet, none of these methods are compatible with mass production of LEDs. In addition, these methods result in high cost, complex LED designs which are sensitive to parameter changes and have a low polarization ratio.

Thus, what is needed is an LED design which provides emission of polarized light without requiring a polarizer, and which provides a low cost, scalable LED design. Furthermore, other desirable features and characteristics will become apparent from the subsequent detailed description and the appended claims, taken in conjunction with the accompanying drawings and this background of the disclosure.

### SUMMARY

According to the Detailed Description, an apparatus for emitting polarized light is provided. The apparatus includes a surface emission light emitting diode (LED), a first electrode, and a sub-wavelength metal grating (SWMG). The surface emission LED includes a first contact surface and a second contact surface. The first electrode is coupled to the first contact surface. The SWMG is formed on a surface of the surface emission LED.

In addition, a method for fabricating a LED for emitting polarized light is provided. The method includes fabricating a surface emission LED comprising a first contact surface and a second contact surface, and fabricating a first electrode on the first contact surface. The method also includes fabricating a SWMG on a surface of the surface emission LED.

Further, another apparatus for emitting polarized light is provided. The apparatus includes a surface emission LED and a SWMG. The surface emission LED includes a first contact surface, a second contact surface and electrode material, the electrode material formed on the second contact surface. And the SWMG is formed on the electrode material to act simultaneously as a polarizer and a transparent contact layer for contacting the second contact surface.

### BRIEF DESCRIPTION OF THE DRAWINGS

The accompanying figures, where like reference numerals refer to identical or functionally similar elements throughout the separate views and which together with the detailed description below are incorporated in and form part of the specification, serve to illustrate various embodiments and to explain various principles and advantages in accordance with the present invention.

FIG. 1, including FIGS. 1A and 1B, illustrate a light emitting diode (LED) with a sub-wavelength metal grating (SWMG) in accordance with a present embodiment, wherein FIG. 1A is a side view and FIG. 1B is a top view of the LED;

FIG. 2 is a graph depicting intensity count vs. wavelength of the polarized light emitted by the LED of FIG. 1 in accordance with the present embodiment;

FIG. 3 is a graph depicting normalized intensity output vs. polarizer angle of the LED of FIG. 1 in accordance with a present embodiment;

FIG. 4, comprising FIGS. 4A, 4B and 4C, illustrate a LED with a SWMG in accordance with an alternate embodiment, wherein FIG. 4A is a side view, FIG. 4B is a top view with a p-contact pad, and FIG. 4C is a top view without a p-contact pad;

FIG. 5, comprising FIGS. 5A and 5B, illustrate a LED with a SWMG in accordance with another alternate embodiment, wherein FIG. 5A is a side view and FIG. 5B is a top view of the LED;

FIG. 6 is a side planar view illustrating a flip-chip LED with a SWMG on a sapphire substrate in accordance with another alternate embodiment; and

FIG. 7 is a side planar view illustrating a membrane LED with SWMG made on N—GaN in accordance with yet another embodiment.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION

The following detailed description is merely exemplary in nature and is not intended to limit the invention or the application and uses of the invention. Furthermore, there is no intention to be bound by any theory presented in the preceding background of the invention or the following detailed description of the invention.

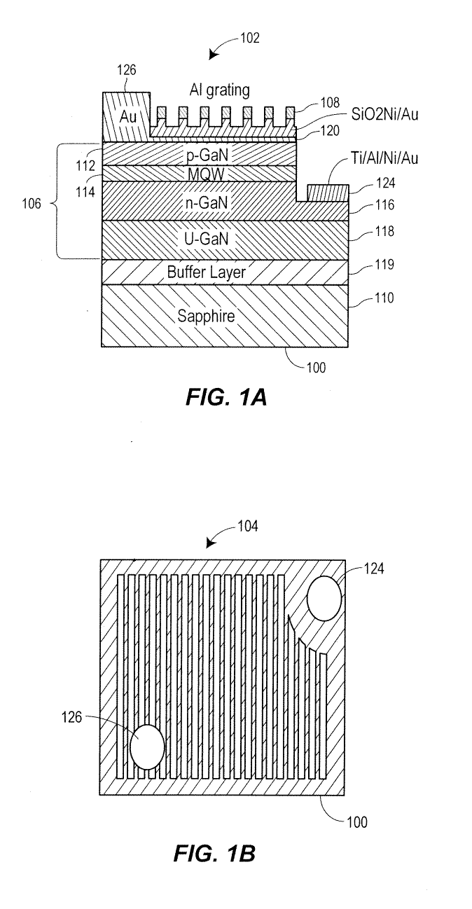

Referring to FIG. 1, an apparatus 100 for emitting polarized light in accordance with a present embodiment is depicted. FIG. 1A is a side planar view 102 of the apparatus 100, while FIG. 1B is a top planar view 104 of the apparatus 100. The apparatus 100 includes a surface emission light emitting diode (LED) 106 with a sub-wavelength metal grating (SWMG) 108. The LED 106 structure is grown on a (0001) sapphire substrate 110 by metal organic chemical vapor deposition. The layered structure of the LED 106 has an approximately two hundred nanometer (200 nm) thick p-GaN layer 112, quantum wells 114, an approximately two thousand nanometer (2000 nm) thick n-GaN layer 116, and an approximately two thousand nanometer (2000 nm) thick u-GaN layer 118. In the example shown in FIG. 1A, the LED 106 is an InGaN/GaN green LED, and the quantum wells 114 comprise InGaN/GaN four quantum wells. The u-GaN layer 118 is formed over a buffer layer 119 on the substrate 110. Standard microelectronic processes, including photolithography, plasma etching, metal deposition and alloying, are used to produce the conventional surface emission LED 106 with both a p contact surface 120 on the p-GaN layer 112 and a n contact surface 122 formed in the n-GaN layer 116.

The mesa area of the LED 106 is about 300 um×300 um. A thin layer of SiO2 is deposited by plasma enhanced chemical vapor deposition on top of the 5 nm/5 nm thick Ni/Au p-type ohmic contact surface 120 to serve as both a protective layer for the p-metal contact surface 120 during an ion-milling process and the insulating layer between the metal grating and p-contact. The thin layer of SiO2 may also be partially etched through or fully etched through, which is found to be beneficial to the polarizing performance of the SWMG 108. An approximately one hundred fifty nanometer (150 nm) thick Al layer is then evaporated on top of the thin layer of SiO2 by thermal evaporation with a thin titanium transition layer to enhance adhesion. Electron beam lithography (EBL) is used to define the grating pattern of the SWMG 108 with a period of approximately one hundred fifty nanometers (150 nms), the pattern being transferred from resist to the Al layer by ion-milling and seen clearly in the top planar view of FIG. 1B.

A metallic n-contact pad 124 is formed as a first electrode coupled to the n-contact surface 122. A metallic p-contact pad 126 is formed as a second electrode coupled to the p-contact surface 120. The contact pads 124, 126 provide electrodes for electrically coupling the polarizing apparatus 100 to external circuitry.

The process described above is exemplary and it will be understood by those skilled in that art that the SWMG 108 can be formed by different methods. For example, the deposition of the dielectric SiO2 layer can be done by sputtering, spin-on glass, or ebeam evaporation. The thin SiO2 layer formed on the contact surface 120 can also be formed from other dielectric materials such as MgF2, Si4N3, Al2O3, ZnSe, ZnO, or TiO2. The metal deposition for the SWMG 108 can be done by sputtering method, e-beam evaporation, as well thermal evaporation. The grating patterning of the SWMG 108 can be formed by ebeam writing, laser writing, two photon absorption, laser interference, nano-imprinting, or EUV lithography, and the metal grating formation can be completed by lift-off, ion-milling, or etching. In addition, the SWMG 108 can also be directly formed by focused ion beam milling.

The present embodiment advantageously provides a scalable SWMG 108 formation process that is compatible with and can be integrally incorporated with the manufacture of the LED 106, such as an InGaN/GaN green LED. The fabrication of the SWMG 108 can be performed after the complete fabrication of the LED 106 structure with p-contact pad 120 already formed, or the SWMG 108 can be formed on the p-metal contact surface 122 before the p-contact pad 126 formation. In the latter case, the p-contact pad 126 may be formed on top of the SWMG 108 structure with the dielectric insulating layer underneath the p-contact pad 126 removed by chemical etching, for example using HF or BHF to remove the SiO2 dielectric insulating layer. The SWMG 108 structure can be square-shaped or can follow the shape of the p-mesa structure.

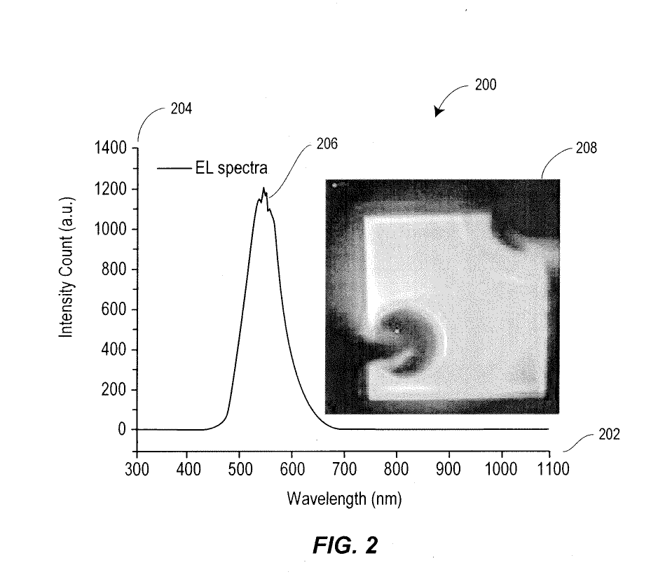

Referring to FIG. 2, a graph 200 depicting a room temperature electroluminescence (EL) spectrum of the polarized light emitted by the apparatus 100 of FIG. 1 in accordance with the present embodiment. The graph 200 plots the wavelength along the x-axis 202 and the light intensity count along the y-axis 204 at a forward current of ten milliamps (10 mA). The peak wavelength and the full width at half maximum (FWHM) of the emission spectra of the apparatus 100 are 546 nm and 80 nm, respectively, as measured from the dimensions of the peak 206. Compared with LED device without the SWMG 108 fabricated thereon (i.e., only the LED 106), both peak wavelength and FWHM are substantially similar, which is consistent with the fact that the SWMG 108 in accordance with the present embodiment provides almost uniform transmission efficiency within the spectrum range of the LED 106. An inset optical micrograph 208 depicts a polarized light emission area which is exclusively defined clearly by the squared electron beam lithographic (EBL) writing area where the SMWG 108 is patterned on the surface (i.e., as opposed to a mesa area defined by optical lithography as present in conventional LEDs). As can be seen in the inset micrograph 208, a planar Al layer in the region outside the EBL writing area was not etched away during ion-milling.

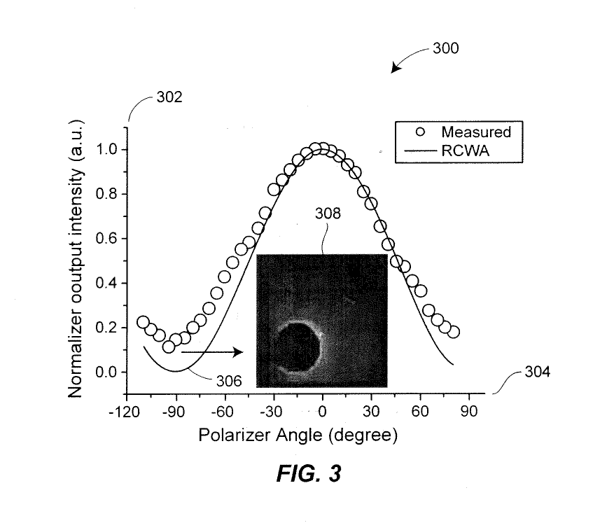

Referring next to FIG. 3, a graph 300 depicts the EL intensity (on the y-axis 302) as a function of the orientation angle (on the x-axis 304) of a linear polarizer placed between the InGaN/GaN green SWMG LED apparatus 100 and a measuring spectrometer. The intensity at various angles is determined from measuring the central wavelength peak intensity of each spectrum taken under different polarizer-rotating angles with five-degree intervals. Only the light components with polarization parallel to the polarizer axis can pass through the polarizer. An InGaN/GaN green LED 106 without the SWMG 108 shows no polarization and the light intensity is almost constant when turning the polarizer in a circle period. From the points plotted on the graph 300 and the resultant curve 306, the measured intensity of light emitted by the apparatus 100, which includes the LED 106 with the Al SWMG 108, varies with the polarizer-rotating angle, thereby revealing that the light emitted by the apparatus 100 is polarized light. The measured polarization ratio, defined as the maximum intensity dived by the minimum intensity Iₘₐₓ/Iₘᵢₙ, is above 7:1. The measured results match well with the simulated results using rigorous coupled-wave analysis (RCWA), as seen in the solid curve 306 in FIG. 3, except around the extinction position at which the simulated curve 306 almost reaches zero for a perfect linear polarization without any orthogonal component. The non-zero orthogonal component in the measured results originated from the leakage light from the P-pad edge areas, as seen in the inset optical micrograph 308. The eclipse-like emission suggests that light around the pad has a lower polarization degree, possibly due to un-conformal deposition of aluminum around the pad from the shadowing effect during e-beam evaporation and the uneven resist resulting in grating pattern distortion around the pad.

The above experiment is just one example. The polarization ratio and the light coupling out efficiency are related to the grating parameters, such as grating period, grating height, and duty cycle. The material used for the SWMG 108 in the examples of FIG. 2 and FIG. 3 is Aluminum. However, other metals, such as silver or gold, could present substantially equivalent effects. The grating parameters and metal composition of the SWMG 108 can be tuned to get the best polarization performance for the LED 106. The device size can be smaller or bigger than the device used in the measurements of FIGS. 2 and 3 and the p-mesa shape can be different.

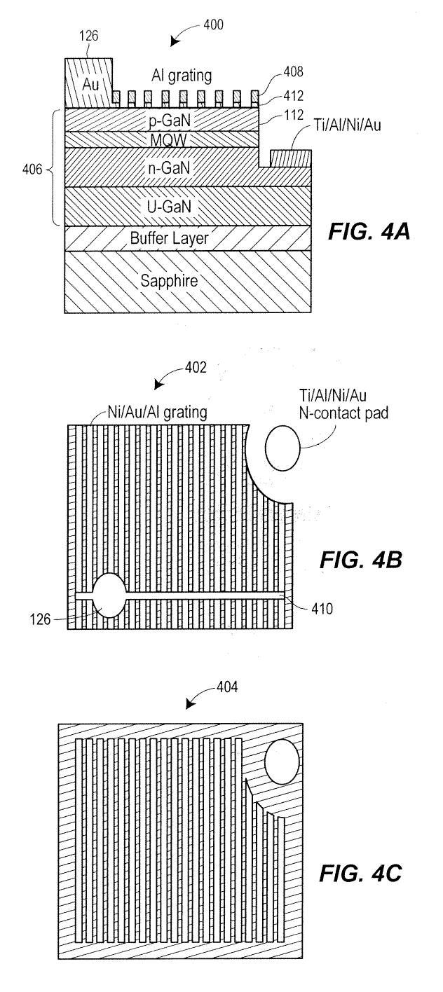

Referring to FIG. 4, comprising FIGS. 4A, 4B and 4C, an LED 406 with a SWMG 408 formed directly on top of the p-GaN layer 112 in accordance with an alternate embodiment is depicted. FIG. 4A is a side planar view 400 of the apparatus 100 in accordance with this alternate embodiment. FIG. 4B is a top planar view 402 depicting the apparatus 100 with the p-contact pad 126, while FIG. 4C is a top planar view 404 of the apparatus 100 without a p-contact pad 126.

The alternate embodiment of the apparatus structure includes the SWMG 408 formed directly on top of the p-GaN layer 112 of the LED 406 during the LED fabrication process. In accordance with this alternate embodiment, the SWMG 408 will be serving as both polarizer and the metal electrode for contact to the p-GaN layer 112, serving as a transparent conducting electrode. To improve ohmic contact as well as polarizer function in the SWMG 408 in accordance with this alternate embodiment, the SWMG 408 can be formed by Ni/Au/AI with in the thicknesses of, for example, 5 nm/5 nm/2000 nm.

In one possible structure 402 in accordance with this alternate embodiment, the p-metal contact pad will have all the grating lines of the SWMG 408 connected by metallized trace 410. This structure will save performing separate steps of Ni/Au and Al metal deposition, as well as plasma enhanced chemical vapor deposition (PECVD) of an SiO2 dielectric layer. In another possible structure 404, the p-contact pad 126 need not be formed within the grating region of the SWMG 408 as the Al grating may be connected to an Al layer outside the grating region, which can serve as a bonding pad. The structure 404 advantageously provides that no light will be blocked due to the p-metal contact pad 126, and that the grating will be formed on the same plateau of the p-mesa with a flat surface, thereby enabling improved performance of the SWMG 408.

In a further structure, the NiAu p-contact layer 412 can be etched to follow the Al grating of the SWMG 408, as seen in FIG. 4A. The partial removal of the Ni/Au contact layer between adjacent Al gratings of the SWMG 408 eliminates the partial transparent problem of the p-contact layer and increase the light output from the LED 406 through the SWMG 408 by ten to twenty-five percent.

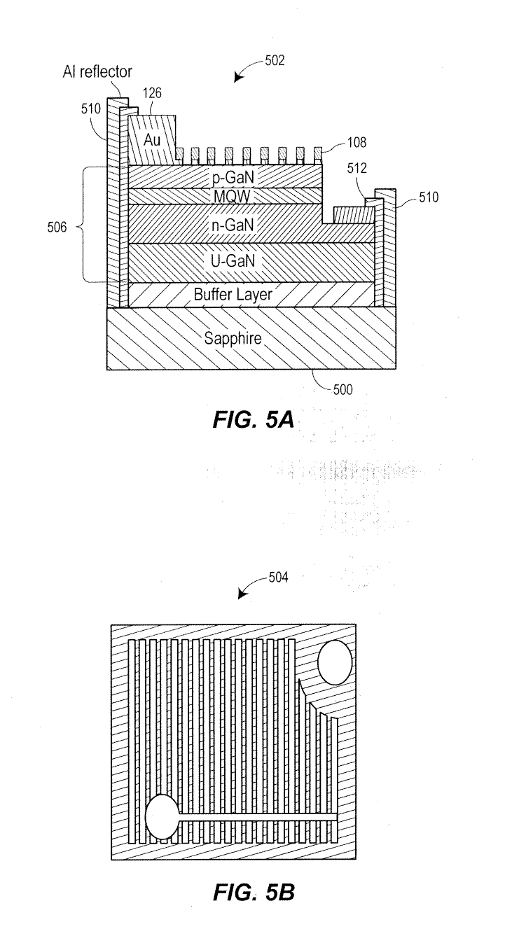

Referring to FIG. 5, comprising FIGS. 5A and 5B, illustrate an apparatus 500 including a LED 506 with a SWMG 508 in accordance with another alternate embodiment is depicted. FIG. 5A illustrates a side planar view 502 of the apparatus 500 and FIG. 5B illustrates a top planar view of the apparatus 500.

For practical applications of LEDs, after fabrication of the LED, it is normally diced into individual chips and packaged. Due to the higher refractive index of the InGaN and GaN layers with respect to that of the substrate sapphire, the InGaN/GaN layer on top of the sapphire substrate will form a waveguide layer facilitating light propagation in a horizontal plane perpendicular to the surface of the substrate. This side-emitting light will be partially emitted from a packaged LED, thus deteriorating the overall device polarization ratio.

Referring to FIG. 5A, this side-emitting light problem can be minimized by mesa etching and metal reflector coating during formation of the apparatus 500. This alternate improvement is equally applicable to the apparatus 100 of FIG. 1A and the apparatus 400 of FIG. 4A. After fabrication of the apparatus 500, the wafer can be patterned and etched using plasma etching to remove the GaN layer down to the sapphire substrate. The trench should be outside the mesa of the LED 506. The width of the trench can be, for example, 20 um, which can be used later as a guiding line for chip dicing. Then the wafer can be coated with a dielectric layer like SiO2 with a thickness of approximately 100 nm using PECVD to act as an electrical isolation layer. A metal layer formed of a metal such as Al with a thickness of 200 nm can be further deposited by e-beam evaporation and lift-off process to form reflective layers 510 on sidewalls of the LED 506 by covering the trench and side wall of the InGaN/GaN layer on top of the sapphire substrate, thereby blocking the side-emitting light propagating from the InGaN/GaN waveguide layer. The reflective layers 510 may include notches 512 which can cover any other part on the p-GaN surface, like the p-mesa edge as shown in the FIGS. 5A and 5B, to eliminate any potential light leakage through the mesa edge. Provision of the reflective layers 510 on the sidewalls of the LED 506 greatly improves the polarization ratio in the packaged apparatus 500.

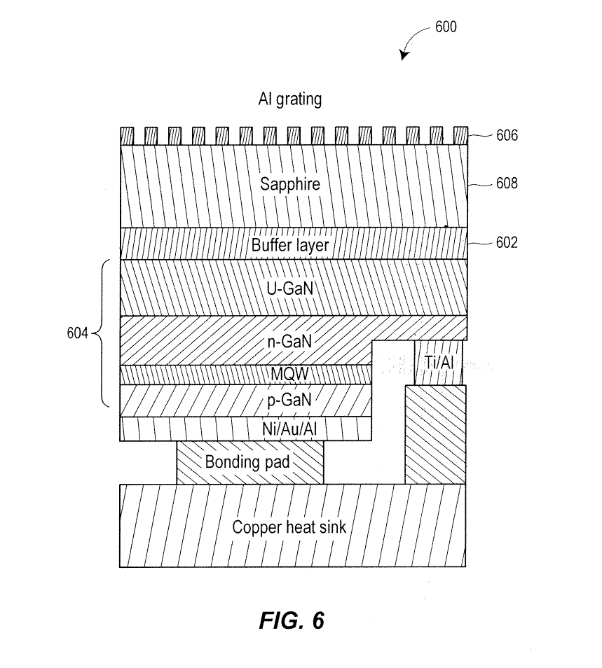

In high brightness LEDs (such as white LEDs or color converted LEDs) with high current injection and under high power operation, the LED can operate with the p-side mounted down in touch with a heat sink, and with the light emission coming through the sapphire substrate. This mounting is carried out with flip-chip technology. The sapphire substrate can also be removed by laser lift-off or photo-electro-chemical etching, and have the p-side in contact with heat sink. Referring to FIG. 6, a side planar view 600 illustrates a flip-chip apparatus 602 with an LED 604 and a SWMG 606. The SWMG 606 is formed on a sapphire substrate 608 in accordance with this other alternate embodiment.

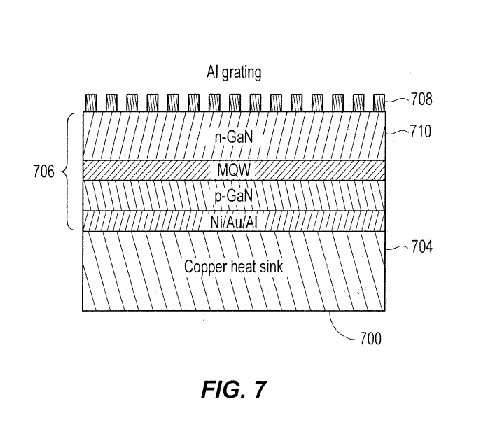

In a like manner, FIG. 7 illustrates a membrane structure 700 wherein the substrate sapphire has been removed and the LED 706 is mounted on a heat sink 704. The SWMG polarizer structure 708 is formed on the n-GaN layer 710.

The SWMG 608, 708 can be formed by ion milling, plasma etching or a lift-off process. In the top surface emission LED structure, the dielectric insulation layer like SiO2 can be partially etched, like to a depth of 100 nm. This will help the light extraction out of the GaN contact surface. Similarly, in the flip-chip LED structure 602 or membrane LED structure 700, the sapphire substrate 608 or the n-GaN layer 710 can be purposefully milled or etched to create an uneven surface structure or roughened metal bonding structure internal to the LED 604, 706 to enhance the light extraction from the apparatus 602, 700.

In the embodiments discussed herein, the active light emitting region of InGaN/GaN based quantum wells (e.g., layer 114, FIG. 1A) could have emission wavelength in the full visible range. In addition, the quantum wells could include InN based quantum dots or In rich InGaN nano-crystals that have either colored emission or direct white light emission. For polarized white light emission from a white LED, the phosphor or quantum dots materials can be coated directly on top of the InGaN/GaN blue or UV LED. In this configuration, the SWMG can be fabricated on top of the flat phosphor or quantum dots layers. The total polarized light emission efficiency could be enhanced by the extra phosphor or quantum dots layers due to their light recycling effect.

Thus it can be seen that an apparatus has been provided which includes a subwavelength metal grating (SWMG) structure fabricated on conventional LEDs available in the market which provides emission of polarized light with a higher extinction ratio. The apparatus includes conventional InGaN/GaN LED structures grown on (1000) Sapphire substrate as is commonly used in the LED fabrication field. No non-polar or semi-polar substrates are required and the SWMG has been proven to generate polarized light. The SWMG in accordance with the present embodiments is easier for fabrication and integration with conventional LED structures, and is much less sensitive to wavelength and device parameters than the photonic crystal method. The extinction ratio that can be achieved by incorporation of the SWMG in accordance with the present embodiments is also potentially much higher. The fabrication process for forming the SWMG is compatible with conventional LED fabrication methods, including flip-chip LED fabrication methods for high power devices and membrane LEDs formed by lifting the LED off the sapphire substrate.

It can further be seen that an apparatus for emitting LED-generated polarized light and a method for fabricating such device have been disclosed which advantageously provide a simple technology to make a LED emitting directly linear polarized light. In addition, a LED has been provided that appears like and operates like a normal LED in operation and provides generation of polarized light without requiring the use of a polarizer panel in the LCD display, thereby saving cost and space. An apparatus in accordance with one or more of the embodiments discussed herein may be used in many applications which require polarized light, such as in mini-projectors and image processing. While at least one exemplary embodiment has been presented in the foregoing detailed description of the invention, it should be appreciated that a vast number of variations exist, such as those discussed in FIGS. 1, 4, 5, 6 and 7 herein.

It should further be appreciated that the exemplary embodiments are only examples, and are not intended to limit the scope, applicability, dimensions, or configuration of the invention in any way. Rather, the foregoing detailed description will provide those skilled in the art with a convenient road map for implementing an exemplary embodiment of the invention, it being understood that various changes may be made in the steps for fabrication and elements of the apparatus described in the exemplary embodiments without departing from the scope of the invention as set forth in the appended claims.

What is claimed is:

1. An apparatus for emitting polarized light comprising:
a surface emission light emitting diode (LED) comprising a first contact surface and a second contact surface;
a first electrode coupled to the first contact surface; and
a sub-wavelength metal grating (SWMG), wherein the SWMG is formed on a surface of the surface emission LED.

2. The apparatus in accordance with claim 1 further comprising a second electrode coupled to the second contact surface.

3. The apparatus in accordance with claim 2 wherein the SWMG is formed on electrode material coupled to the second contact surface, the SWMG comprising the second electrode.

4. The apparatus in accordance with claim 1 wherein the SWMG comprises a metal selected from the group of metals comprising Al, Ag, Au, other metals and combinations of any such metals formed over a thin dielectric layer comprising a dielectric selected from the group of dielectrics comprising SiO2, MgF2, Si4N3, Al2O3, ZnSe, ZnO, and TiO2.

5. The apparatus in accordance with claim 1 wherein the surface emission LED is a white LED or color converted LED, and wherein the SWMG is formed on a phosphor layer of the white LED or color converted LED.

6. The apparatus in accordance with claim 1 wherein the surface emission LED is a flip-chip LED, and wherein the SWMG is formed on a substrate of the surface emission LED.

7. The apparatus in accordance with claim 1 further comprising reflective layers formed on sidewalls of the surface emission LED for reduction of side emission of light from the surface emission LED.

8. The apparatus in accordance with claim 1 wherein the surface emission LED includes a structure for reflection of light back to the emission surface.

9. A method for fabricating a light emitting diode (LED) for emitting polarized light, the method comprising:
fabricating a surface emission LED comprising a first contact surface and a second contact surface;
fabricating a first electrode on the first contact surface; and
fabricating a sub-wavelength metal grating (SWMG) on a surface of the surface emission LED.

10. The method in accordance with claim 9 further comprising fabricating a second electrode on the second surface.

11. The method in accordance with claim 9 further comprising fabricating a layer of electrode material on the second contact surface, wherein the step of fabricating the SWMG comprises fabricating the SWMG on the layer of electrode material so that the SWMG functions as a second electrode.

12. The method in accordance with claim 9 wherein the step of fabricating the SWMG comprises fabricating the SWMG in accordance with a fabrication method compatible with conventional InGaN/GaN LED fabrication.

13. The method in accordance with claim 9 wherein the step of fabricating the SWMG comprises fabricating the SWMG in accordance with a patterning method selected from the group of patterning methods comprising focused ion beam milling or a two-step method comprising a first step selected from the group of method steps comprising electron beam writing, laser writing, two photon absorption, laser interference, nano-imprinting, and extreme ultraviolet lithography, followed by a second step selected from the group of steps comprising lift-off, ion milling, plasma etching, and chemical etching.

14. The method in accordance with any of claim 9 wherein the step of fabricating the surface emission LED comprises fabricating white LED, and wherein the step of fabricating the SWMG comprises forming the SWMG on a phosphor layer of the white LED.

15. The method in accordance with claim 9 wherein the step of fabricating the surface emission LED comprises forming the surface emission LED on a substrate and fabricating a flip-chip LED, and wherein the step of fabricating the SWMG comprises forming the SWMG on substrate of the surface emission LED.

16. The method in accordance with claim 9 further comprising forming insulative and/or reflective layers on sidewalls of the surface emission LED to reduce side emission of light from the surface emission LED.

17. The method in accordance with claim 9 wherein the step of fabricating the surface emission LED comprises fabricating a structure internal to the surface emission LED for reflection of light.

18. The method in accordance with claim 17 wherein the step of fabricating a structure internal to the surface emission LED for reflection of light comprises forming roughened metal bonding within the surface emission LED for reflection of light.

19. An apparatus for emitting polarized light comprising:
a surface emission light emitting diode (LED) comprising a first contact surface, a second contact surface, and electrode material formed on the second contact surface; and
a sub-wavelength metal grating (SWMG), wherein the SWMG is formed on the electrode material to act simultaneously as a polarizer and a transparent contact layer for contacting the second contact surface.

20. The apparatus in accordance with claim 19 wherein said electrode material comprises a NiAu alloy.
